(19) United States
(12) Patent Application Publication
(10) Pub. No.: US 2004/0109570 A1
(43) Pub. Date: Jun. 10, 2004

(54) System and method for selective signal cancellation for multiple-listener audio applications

(76) Inventors: Sunil Bharitkar, Los Angeles, CA (US); Chris Kyriakakis, Altadena, CA (US)

Correspondence Address: Evan M. Kent, Esq., MITCHELL SILBERBERG & KNUPP, 11377 West Olympic Boulevard, Los Angeles, CA, 90064-1683, US

(21) Appl. No.: 10/465,237

(22) Filed: Jun. 20, 2003

Related U.S. Application Data
(60) Provisional application No. 60/390,121, filed on Jun. 21, 2002.

(51) Int. Cl. H04R 5/00; H03G 3/00

(52) U.S. Cl. 381/17; 381/305; 381/61

(57) ABSTRACT

A system and method for producing an audio output directed to a listening environment having at least two listening positions. Based upon the location of a loudspeaker for the purpose of producing an audio output and the physical location of the listening positions, the audio output would be preprocessed by one or more filters whose coefficients would maximize the signal heard by a listener in one of the listening positions and constrained by a listener in another position, thereby eliminating or minimizing the audio output heard by a listener in one of the other positions.

### CROSS-REFERENCE TO RELATED APPLICATIONS

The contents of this application are related to provisional patent application Serial No. 60/390,121, filed on Jun. 21, 2002. The contents of this related provisional patent application are incorporated herein by reference.

### BACKGROUND OF THE INVENTION

1. Field of the Invention

The present invention relates to the field of presenting an audio signal to at least one listener in a particular environment while cancelling or minimizing that same audio signal presented to at least a second individual in that same environment.

2. Description of the Prior Art

Integrated media systems are envisioned to have a significant impact on the way groups of people in remote locations communicate with each other. One of the critical elements that help enhance the suspicion of disbelief required to convince people that they are truly in the same environment is sound. While a great deal of ongoing research is focused on the problem of delivering high quality sound to a single listener, the problem of delivering the appropriate audio signals to multiple listeners in the same environment has not been adequately addressed. For example, in situations where an audio signal is to be maximized at one position in an environment and minimized or cancelled completely in a second position of that environment, traditional noise cancellation would provide a signal which is opposite in phase to the primary signal. The problem with this method is that various sensors must be placed on all of the listeners to adequately provide such signals.

Several methods have been proposed to lower the signal level either globally or in a local space within a region. Such an approach would utilize a global act of power maximization technique for reducing the time average acoustic pressure from a primary source in an enclosure using a set of secondary source distributions. This least-squares based technique demonstrated that reduction in potential energy (and therefore sound pressure) can be achieved if the secondary sources are separated from the primary source by a distance which is less than half the wavelength of sound at the frequency of interest. It was suggested that this method can be employed to reduce the cockpit noise in a propeller powered aircraft. Similarly, a second technique suggested the use of a filter that can minimize the signal power in the lobby of a building due to a generator outside the lobby by blocking the dominant plane wave mode with a loud speaker. Other techniques could include head mounted reference sensors using adaptive beamforming techniques.

However, none of these techniques adequately address the situation in which audio signals are selectively cancelled at specific locations within an acoustical environment with multiple listeners, such as a home theater, an automobile, a teleconferencing environment, an office as well as other industrial applications. This is particularly true in the situation that one or more of the listeners in the environment would wish to be presented with the audio signal and yet one or more other listeners in the environment would want the audio signal to be cancelled or at least greatly minimized.

### OBJECTS OF THE INVENTION

Consequently, one object of the present invention would be to develop a method and system to produce an audio signal maximally received by one or more listeners in a particular environment, the same signal cancelled or greatly minimized to one or more other listeners in that same environment.

Yet another object of the present invention would be to create a filter to produce a signal in a particular environment which is maximized at one or more locations in that environment but is minimized or cancelled completely in one or more other locations in that environment.

Yet another object of the present invention would be to create a system for measuring the acoustical response from one or more locations in a particular environment and then creating a filter to produce an audio output based upon the positions in the environment that would require a maximized signal in those positions in the environment as well as a minimized or cancelled signal to other positions in the environment.

### SUMMARY OF THE INVENTION

The foregoing objects of the present invention as well as other objects of this invention are addressed by the present invention which involves maximizing an audio signal at selected positions in the environment, while simultaneously minimizing or cancelling the signal at other positions in the environment. For example, in home theater or television viewing applications, a listener in a specific location in the environment may not want to listen to the audio signal being transmitted, while another listener in a different location would prefer to listen to the signal. Consequently, if one of the objects of the present invention is to present one listener in that environment with a reduced sound pressure level, then one can view this problem as that of signal cancellation in the position of the listener that does not wish to receive the signal. Similar applications arise in the automobile environment in which one or more listeners would prefer to hear a signal produced by a radio, CD player or cassette while other listeners in that environment would not wish to listen to that audio signal.

The present invention approaches the problem of signal cancellation by designing objective functions that aim at producing the sound pressure levels of signals in pre-determined directions or positions. A first objective criteria or function is designed for maximizing the difference in signal power between two or more different listener locations that have different source-receiver response characteristics. For the purpose of this invention, we will require that the listeners represent point receivers and we do not consider the effects of each listeners head-related transfer functions (HRTF).

The system and method of the present invention would measure an acoustical response to a test signal by placing a transceiver at one or more locations in the environment. A filter such as an eigenfilter would be derived by optimizing the objective function by operating on a raw or unprocessed signal before the signal is linearly transformed by the room responses in the direction of the listeners. If there are only two listeners in the environment, the present invention would derive two sets of coefficients for the eigenfilter. One of these sets of coefficients would be utilized if the first listener wishes to hear the audio signal and the second listener does not wish to hear the audio signal and a second set of coefficients if the second listener wishes to hear the audio signal but the first listener does not wish to hear the audio signal. Based upon which listener wishes to hear the signal, the filter of the present invention would process the raw signal through the eigenfilter having the proper set of coefficients to produce the correct signal including the correct gain to allow one of the listeners to properly hear the audio signal and the second listener to hear what appears to be a minimized or cancelled signal. If both of the listeners wish to hear the audio signal, the raw signal would be required to pass through the eigenfilter.

In the situation in which the environment includes more than two positions for the listeners, the test signal would be generated when the transceiver is in each of the positions. In this instance, the acoustical responses generated by the test would be average to provide the proper coefficients of the eigenfilter.

In the situation in which only two listeners are present in the environment, the eigenfilter would aim at increasing the relative gain in signal power between the two listeners with some associated trade offs. These trade offs would include spectral distortion that may arise from the presence of the eigenfilter and the sensitivity of the eigenfilter to the length of the room impulse response (reverberation).

### BRIEF DESCRIPTION OF THE DRAWINGS

The foregoing and other features and objects of the present invention will be described in detail herein with reference to the accompanying drawings, in which:

FIG. 1 is a block diagram of a single source-dual listener environment utilizing the filter of the present invention;

FIG. 2 is a diagram showing the effect of gain maximization of two listeners in a single environment;

FIG. 3 is a speech signal utilized to test the teachings of the present invention;

FIG. 4 is a graph of an impulse response taken from two positions in an environment;

FIG. 5 is a graph of the eigenfilter performance as a function of the eigenfilter order;

FIG. 6 is an equivalent spectral model in the direction of a second listener using the eigenfilter wₙ;

FIG. 7 is a graph showing the eigenfilter distortion as a function of the eigenfilter order M;

FIG. 8 is a graph summarizing the results from FIGS. 5 and 7;

FIG. 9A is a graph showing the performance of the eigenfilter where M=64 and P=64;

FIG. 9B shows the eigenfilter design where M=64 and P=128;

FIG. 9C shows the eigenfilter where M=64 and P=512;

FIG. 10A shows the eigenfilter design where M=128 and P=128;

FIG. 10B shows the eigenfilter design where M=128 and P=236;

FIG. 10C shows the eigenfilter design where M=128 and P=512;

FIG. 11A shows the eigenfilter design where M=256 and P=256;

FIG. 11C shows the eigenfilter design where M=236 and P=512;

FIG. 12A shows a graph of the performance of the eigenfilter for minimum phase room impulse response models where M=64 and P=64;

FIG. 12B shows a graph of the eigenfilter performance for minimum phase room impulse models where M=64 and P=128;

FIG. 12C shows a graph of the eigenfilter design performance for minimum phase room impulse response models where M=64 and P=512;

FIG. 13A shows a graph of the eigenfilter design performance for minimum phase room impulse response models where M=128 and P=128;

FIG. 13B shows a graph of the eigenfilter performance for minimum phase room impulse response models where M=128 and P=256;

FIG. 13C shows a graph of the performance of the eigenfilter for minimum phase room impulse response models where M=128 and P=512;

FIG. 14A shows a performance of the eigenfilter for minimum phase room impulse response models where M=256 and P=256;

FIG. 14B shows the performance of the eigenfilter for minimum phase room impulse response models where M=256 and P=512;

FIG. 15 shows a block diagram of a multi-speaker, multi-listener environment; and

FIG. 16 illustrates a flow diagram of the method and system of the present invention.

### DETAILED DESCRIPTION OF THE INVENTION

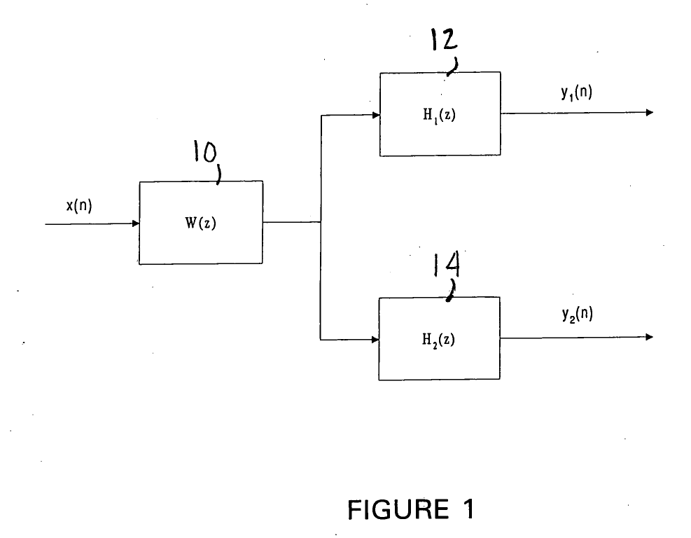

One of the objects of the present invention is to develop a filter for the purpose of processing a raw audio signal to produce a processed audio signal allowing one or more listeners to hear the audio signal while at the same time minimizing or cancelling that audio signal to other listeners located at different positions in the same environment. Although the applications of the present invention can be applied to more than two listeners in the same environment, for the initial discussion of the development of the eigenfilter to be utilized, we will limit our discussion to the single source and dual listener environment illustrated in FIG. 1. After this eigenfilter has been developed, its application to a three or more listener environment will be discussed.

It is well established from linear system theory that

$${y}_{i} ( n ) = {\sum }_{k = 0}^{P - 1} {h}_{i} ( k ) x ( n - k ) + {v}_{i} ( n ) i = 1 , 2 \qquad ( 1 )$$

where, x(n) is the primary signal transmitted by a source, such as a loudspeaker; yᵢ(n) is the signal received at listener Rᵢ;hᵢ is the room transmission characteristic or room impulse response (modeled as a finite impulse response) between the source and listener Rᵢ; and, vᵢ is additive (ambient) noise at listener Rᵢ. In a reverberant environment, due to multipath effects, the room responses vary with even small changes in the source-receiver locations, and in general h₁(n)≠h₂(n).

One method of modifying the transmitted primary signal x(n) is to preprocess the source signal by a filter before transmitting it through the environment. Another method of modifying the transmitted signal is by means of filters that are designed for secondary sources (or loudspeakers), wherein the secondary sources alter the primary signal in a predetermined manner. The filters specifically designed for altering the transmitted primary signal power by either of the two methods are known as eigenfilters.

Under our assumption of modeling the listeners as point receivers we can set up the situation as shown in FIG. 1, where wₖ;k=0,1 . . . ,M−1 represents the coefficients of the finite impulse response filter to be designed as denoted by 10 as wₖ. For this problem, we assume that the receivers are stationary (i.e., the room impulse response for a certain (C,R) is time invariant and linear, where C and R represent a source and a receiver), and the channel (room) impulse response is deterministic at the locations of the two listeners. We also assume that we wish to minimize the signal received by listener 1 and maximize the signal received by listener 2. The listening model is then simply related to (1), but the resulting transmitted primary signal is now filtered by wₖ. Thus, the signal yᵢ(n) at listener Rᵢ, with the filter wₖ present, is

$${y}_{i} ( n ) = {h}_{i} ( n ) ⊗ {\sum }_{k = 0}^{M - 1} {w}_{k} x ( n - k ) + {v}_{i} ( n ) i = 1 , 2 \qquad ( 2 )$$

where [symbol] represents the convolution operation. H₁(z)12 and H₂(Z)14 represent the reverberation with respect to the first or second listener. With this background, we view the signal cancellation problem as a gain maximization problem (between two arbitrary receivers), we can state the performance criterion or objective function as,

$$J ( n ) = {max}_{\underline{w}} \frac{1}{2} ( \frac{{σ}_{{y}_{2} ( n )}^{2}}{{σ}_{{v}_{2} ( n )}^{2}} ) - \frac{λ}{2} ( \frac{{σ}_{{y}_{1} ( n )}^{2}}{{σ}_{{v}_{1} ( n )}^{2}} - ψ ) \qquad ( 3 )$$

in which we would like to maximize the signal to noise ratio (or signal power) in the direction of listener 2, while keeping the power towards listener 1 constrained at 10^{ψdB/}^{⁰} (where ψdB=10 log 10ψ). In (3), σ²yᵢ(n)/σ²vᵢ(n) denotes the transmitted signal to ambient noise power at listener Rᵢ with yᵢ(n) as defined in (2). The quantity λ is the well known Lagrange multiplier. The first term in the objective function (3) maximizes the second pressure level and the second term of the objective function is used to constrain the sound pressure level of the audio signal by a predetermined amount.

In another aspect of the invention, the objective function (3) can be re-written as equation (3.1) below.

$$J ( n ) = {max}_{\underline{w}} \frac{1}{2} ( \frac{{σ}_{{y}_{1} ( n )}^{2}}{{σ}_{{v}_{1} ( n )}^{2}} ) - \frac{λ}{2} ( \frac{{σ}_{{y}_{2} ( n )}^{2}}{{σ}_{{v}_{2} ( n )}^{2}} - ζ ) \qquad ( 3.1 )$$

In this situation, the signal power (or sound pressure level) is minimized at listener 1, but the signal power at listener 2 is kept higher by an amount ζ.

While, the objective functions (3) and (3.1) and the corresponding filters are designed for two listeners, it is easy to adapt the objective functions (and filters) to more than two listeners. For example, if the signal power (i.e., sound pressure level or SPL) at listeners 1, 2, 3 is to be minimized, and signal power at listeners 4, 5, and 6 is to be kept above (or retained) by a certain amount, then the process could involve:

1. Recording the room impulse response at all of these expected listeners positions (i.e., h₁(n), h₂(n), h₃(n), h₄(n), h₅(n), and h₆(n)

2. Forming the average as,

$${h}_{avg , minimize} ( n ) = \frac{1}{3} {\sum }_{i = 1}^{3} {h}_{i} ( n ) ; {h}_{avg , retain} ( n ) = \frac{1}{3} {\sum }_{i = 4}^{6} {h}_{i} ( n ) \qquad ( 3.2 )$$

3. Instead of (2) and (3.1), the following equations may then be used for designing the filter for minimizing the SPL at listeners 1, 2 and 3, while retaining the SPL at listeners 4, 5, 6 above by amount τ=(v_{ambient}(n) is ambient noise)

$$\begin{matrix}{y}_{minimize} ( n ) = {h}_{avg , minimize} ( n ) ⊗ {\sum }_{k = 0}^{M - 1} {w}_{k} x ( n - k ) + {v}_{ambient} ( n ) & ( 3.3 ) \\ {y}_{retain} ( n ) = {h}_{avg , retain} ( n ) ⊗ {\sum }_{k = 0}^{M - 1} {w}_{k} x ( n - k ) + {v}_{ambient} ( n ) & ( 3.4 ) \\ J ( n ) = {min}_{\underline{w}} \frac{1}{2} ( \frac{{σ}_{{y}_{minimize} ( n )}^{2}}{{σ}_{{v}_{ambient} ( n )}^{2}} ) + \frac{λ}{2} ( \frac{{σ}_{{y}_{retain} ( n )}^{2}}{{σ}_{{v}_{ambient} ( n )}^{2}} - τ ) & ( 3.5 )\end{matrix}$$

4. Alternatively, in lieu of equation (2) and (3), the following objective function and equations may be used for designing the filter:

$$\begin{matrix}J ( n ) = {min}_{\underline{w}} \frac{1}{2} ( \frac{{σ}_{{y}_{retain} ( n )}^{2}}{{σ}_{{v}_{ambient} ( n )}^{2}} ) - \frac{λ}{2} ( \frac{{σ}_{{y}_{minimize} ( n )}^{2}}{{σ}_{{v}_{ambient} ( n )}^{2}} - v ) & ( 3.6 ) \\ {y}_{minimize} ( n ) = {h}_{avg , minimize} ( n ) ⊗ {\sum }_{k = 0}^{M - 1} {w}_{k} x ( n - k ) = {v}_{ambient} ( n ) & ( 3.7 ) \\ {y}_{retain} ( n ) = {h}_{avg , retain} ( n ) ⊗ {\sum }_{k = 0}^{M - 1} {w}_{k} x ( n - k ) + {v}_{ambient} ( n ) & ( 3.8 )\end{matrix}$$

It is interesting to see that, when x(n) and v(n) are mutually uncorrelated, the two terms in the objective function (3) are structurally related to the mutual information between the source and listeners R₂ and R₁ respectively under gaussian noise assumption.

Now observe that,

$${y}_{1} ( n ) = {h}_{1} ( n ) ⊗ {\sum }_{k + 0}^{M - 1} {w}_{k} x ( n - k ) + {v}_{1} ( n ) \qquad ( 4 )$$

where, h₁(n) is the room response in the direction for listener labeled 1. Let w=(w₀,w₁, . . . w_{M-1})^{T}, and x(n)=(x(n),x(n−1), . . . ,x(n−M+1))^{T}, then (4) can be expressed as,

$$\begin{matrix}{y}_{i} ( n ) = {h}_{1} ( n ) ⊗ {\underline{w}}^{T} \underline{x} ( n ) + {v}_{1} ( n ) \\ = {h}_{1} ( n ) ⊗ z ( n ) + {v}_{1} ( n ) \\ = {\sum }_{p = 0}^{L - 1} {h}_{1} ( p ) z ( n - p ) + {υ}_{1} ( n )\end{matrix} \qquad ( 5 )$$

where, z(n)=w^{T}x(n). We assume that the zero mean noise and signal are real and statistically independent (and uncorrelated in the gaussian case). In this case signal power in the direction of listener 1 is,

$$\begin{matrix}{σ}_{y1 ( n )}^{2} = E \{ {\sum }_{p = 0}^{L - 1} {\sum }_{p = 0}^{L - 1} {h}_{1} ( p ) {h}_{1} ( q ) z ( n - p ) {z}^{T} ( n - q ) \} + {σ}_{v1 ( n )}^{2} \\ = {\sum }_{p = 0}^{L - 1} {\sum }_{q = 0}^{L - 1} {h}_{1} ( p ) {h}_{1} ( q ) ( {\underline{w}}^{T} {R}_{\underline{x}} ( p . q ) \underline{w} ) + {σ}^{2} {v}_{i} ( n )\end{matrix} \qquad ( 6 )$$

where, w ∈ R^{M},Rₓ(p,q)∈ R^{M×M}, and

Rₓ(p,q)=E{x(n−p)x^{T}(n−q)}

x(n−l)=(x(n−l), . . . ,x(n−l−M+1))^{T} (7)

Similarly,

$${σ}_{y2 ( n )}^{2} = {\sum }_{p = 0}^{S - 1} {\sum }_{q = 0}^{S - 1} {h}_{2} ( p ) {h}_{2} ( q ) ( {\underline{w}}^{T} {R}_{\underline{x}} ( p , q ) \underline{w} + {σ}_{v2 ( n )}^{2} \qquad ( 8 )$$

Solving ∇_{w}J(n)=0, will provide the set of optimal tap coefficients. Hence from (3), (6), and (8), we obtain

$$\frac{\partial J ( n )}{\partial \underline{w}} = \frac{1}{{σ}_{{v}_{2} ( n )}^{2}} {\sum }_{p = 0}^{S - 1} {\sum }_{q = 0}^{S - 1} {h}_{2} ( p ) {h}_{2} ( q ) {R}_{\underline{x}} ( p , q ) {\underline{w}}^{*} - \frac{λ}{{σ}_{{v}_{1 ( n )}}^{2}} {\sum }_{p = 0}^{L - 1} {\sum }_{q = 0}^{L - 1} {h}_{1} ( p ) {h}_{1} ( q ) {R}_{\underline{x}} ( p , q ) {\underline{w}}^{*} = 0 ; \qquad ( 9 )$$

where ω* denotes the optimal coefficients. Let,

$$A = {\sum }_{p = 0}^{S - 1} {\sum }_{q = 0}^{S - 1} {h}_{2} ( p ) {h}_{2} ( q ) {R}_{\underline{x}} ( p , q ) \\ B = {\sum }_{p = 0}^{L - 1} {\sum }_{q = 0}^{L - 1} {h}_{1} ( p ) {h}_{1} ( q ) {R}_{\underline{x}} ( p , q ) \qquad ( 10 )$$

By assuming equal ambient noise powers at the two receivers (i.e., a σ²v₂(n)=σ²v₁(n)), (9) can be written as

$$\frac{\partial J ( n )}{\partial \underline{w}} {\vert}_{\underline{w} = {\underline{w}}^{*}} = ( {B}^{- 1} A - λ I ) {\underline{w}}^{*} = 0 \qquad ( 11 )$$

The reason for arranging the optimality condition in this fashion is to demonstrate that the maximization is in the form of an eigenvalue problem, (i.e., the eigenvalues corresponding to the matrix B⁻¹A ), with the eigenvectors being w. Strictly speaking, in the free field, the gain based on the inverse square law, is expressed as, Q=10 log ₁₀r²₁/r₂² (dB), where r₁,r₂ are the radial distances of listeners R₁ and R₂ from the source. There are in general M distinct eigenvalues for the M×M matrix B⁻¹A, with the largest eigenvalue corresponding to the maximization of the ratio of the signal powers between receiver 2 (listener 2) and receiver 1 (receiver 1). The optimal filter that yields this maximization is given by,

w*=e_{λmax[B}_{⁻¹}_{A]} (12)

where, e_{λmax[B}_{⁻¹}A] denotes the eigenvector corresponding to the maximum eigenvalue λₘₐₓ of B⁻¹A. A finite impulse response (FIR) filter whose impulse response corresponds to the elements of an eigenvector is called an eigenfilter. Finally, the gain between the two receiver locations can be expressed as,

$$Gdb = 10 {log}_{10} \frac{{}_{y2}^{σ2} ( n )}{{}_{y1 ( n )}^{σ2}} \\ = 10 {log}_{10} \frac{{\underline{w}}^{* T} A {\underline{w}}^{*}}{{\underline{w}}^{* T} B {\underline{w}}^{*}} \qquad ( 13 )$$

Clearly it can be seen from (13) that, the optimal filter coefficients are determined by the channel responses between the source and the two listeners. The degrees of freedom for the eigenfilter is the order M of the eigenfilter.

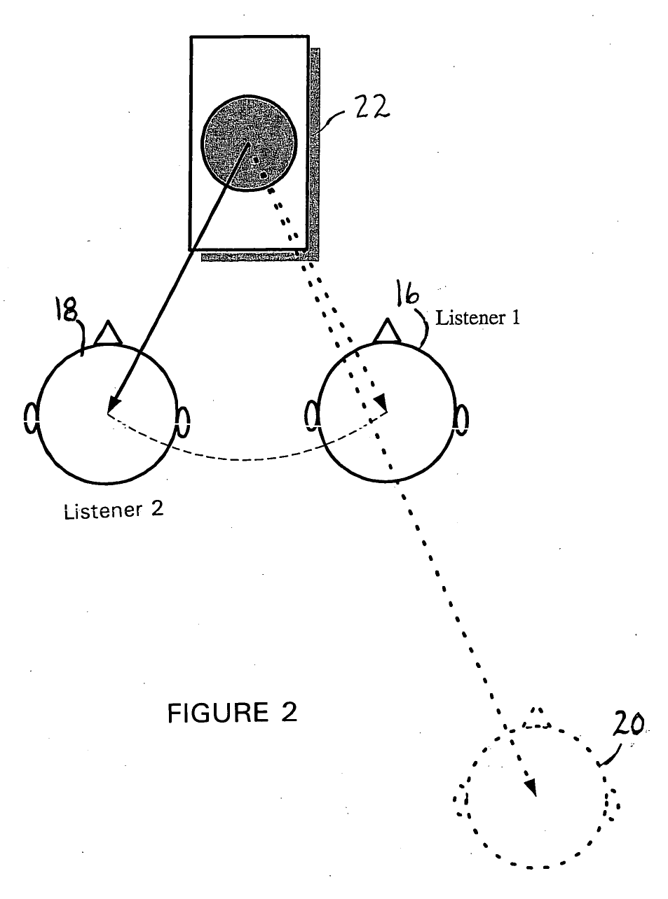

Fundamentally, by recasting the signal cancellation problem as a gain maximization problem, a gain of G dB is introduced between two listeners, R₁ (16) and R₂ (18). This G dB gain is equivalent to virtually positioning listener R₁ at a distance which is \sqrt{10^{G}_{db}/¹⁰} the distance of listener R₂ from a fixed sound source C. This is depicted in FIG. 2, where R1 is denoted as 16 is experiencing signal power levels that he would expect if he was positioned at a distance \sqrt{10^{G}_{db}/¹⁰} from the fixed sound source 22. This fixed sound source can also receive a signal from the listening environment as will be subsequently explained.

Some interesting properties of the proposed eigenfilter emerge under wide-sense stationary (WSS) assumptions. In signal processing applications, the statistics (ensemble averages) of a stochastic process are often independent of time. For example, quantization noise exhibits constant mean and variance, whenever the input signal is “sufficiently complex”. Moreover, it is also assumed that the first and second order probability density functions (pdf's) of quantization noise are independent of time. These conditions impose the constraint of stationarity. Since we are primarily concerned with signal power, which is characterized by the first and second order moments (i.e., mean and correlation), and not directly with the pdf's, emphasis is applied on the wide-sense stationarity (WSS) aspect. It should be noted that in the case of gaussian processes, wide-sense stationarity is equivalent to strict-sense stationarity, which is a consequence of the fact that gaussian processes are completely characterized by the mean and variance.

For a WSS process x(n), and y(n) with finite variances, the matrix Rx(p,q) is toeplitz, and the gain (13) can be expressed as,

$${G}_{db} = 10 {log}_{10} \frac{{{\int }_{2 π}^{} \vert W * {ⅇ}^{jω} ) \vert }^{2} {\vert {H}_{2} ( {ⅇ}^{jω} ) \vert}^{2} {S}_{x} ( {ⅇ}^{jω} ) ⅆ ω}{{{\int }_{2 π}^{} \vert W * {ⅇ}^{jω} ) \vert }^{2} {\vert {H}_{1} ( {ⅇ}^{jω} ) \vert}^{2} {S}_{x} ( {ⅇ}^{jω} ) ⅆ ω} \qquad ( 14 )$$

where, rₓ(k) ∈ Rₓ(k) and Sₓ(e^{jω}) form a Fourier transform pair, and h₁(n) and h₂(n) are stable responses. Moreover, since we are focusing on real processes, the matrix Rₓ(k) is a symmetric matrix, with

rₓ(k)=rₓ(−k) (15)

Toeplitz matrices belong to a class of persymmetric matrices. A p×p persymmetric matrix Q satisfies the following relation,

Q=JQJ (16)

where J is a diagonal matrix with unit elements along the northeast-southwest diagonal. Basically, premultiplying (postmultiplying) a matrix with J exchanges the rows (columns) of the matrix.

The eigenfilter design in the WSS case requires the inversion of a scaled toeplitz matrix (via the room response), and multiplication of two matrices.

It is noted that a scaling term—c, associated with a persymmetric matrix leaves its persymmetricity unaltered. This can be easily seen as follows,

JcQJ=cJQJ=cQ (17)

It is also noted that a linear combination of persymmetric matrices yields a persymmetric matrix.

$$J [ {c}_{1} {Q}_{1} + {c}_{2} {Q}_{2} ] J = {c}_{1} {JQ}_{1} J + {c}_{2} {JQ}_{2} J \\ = {c}_{1} {Q}_{1} + {c}_{2} {Q}_{2} \qquad ( 18 )$$

Hence, from the above properties, the matrices A and B (in (10)) are persymmetric.

It is further noted the inverse of a persymmetric matrix is persymmetric.

Q=JQJ

Q⁻¹=(JQJ)⁻¹=J⁻¹Q⁻¹J⁻¹=JQ⁻¹J (19)

Additionally it is noted that the product of persymmetric matrices is persymmetric.

Q₁Q2=JQ₁JJQ₂J=JQ₁Q₂J (20)

where, we have used the fact that JJ=J²=I. Thus, B⁻¹A is persymmetric.

Based upon the foregoing, it can prove that the roots of the eigenfilter corresponding to a distinct maximum eigenvalue, lie on the unit circle for a toeplitz Rₓ(p,q)=Rₓ(k).

If Q is persymmetric with distinct eigenvalues, then Q has ┌p/2┐ symmetric eigenvectors, and └p/2┘ skew symmetric eigenvectors, where ┌x┐(└x┘) indicates the smallest (largest) integer greater (less) than or equal to x.

A persymmetric matrix is not symmetric about the main diagonal, hence the eigenvectors are not mutually orthogonal. However, in light of the present theory we can prove the following theorem.

It can also be proven that skew-symmetric and symmetric eigenvectors for persymmetric matrices are orthogonal to each other.

Let,

V₁{w:Jw=w}

V₂=w:Jw=−w}

Now,

Jv₁;v₁ ∈ V₁ (22)

then with v₂ ∈ V₂ we have,

v₂^{T}Jv₁=v₂^{T}v₁ (23)

But,

Jv₂=−v₂ [symbol] v₂^{T}J=−v₂^{T} (24)

using the fact the J^{T}=J. Substituting (24) into (23) results

−v₂^{T}v₁=v₂^{T}v₁ [symbol] v₂^{T}v₁=0 (25)

which proves our supposition.

From the unit norm property of eigenfilters (∥w*∥²=1), and parsevals relation, we have

∫_{2π}|W*(e^{jw})^{|2}dw=2π (26)

The eigenvectors associated with B⁻¹A satisfy either,

Jw=w symmetric

Jw=−w skew−symmetric (27)

It finally can be proven that the optimal eigenfilter (12) is a linear phase FIR filter having a constant phase and group delay (symmetric case), or a constant group delay (skew-symmetric case).

w*(m)=w*(M−1−m)symmetric

w*(m)=−w*(M−1−m)skew−symmetric

m=0,1, . . . , M−1 (28)

since J, in (27), exchanges the elements of the optimal eigenfilter.

The “degrees of freedom” for the eigenfilter in (12), is the order −M. Variabilities such as the choice for the modeled duration (S,L) for the room responses (10), the choice of the impulse response (i.e., whether it is minimum phase or non-minimum phase), and variations in the room response due to listener (or head) position changes affect the performance (gain). It is assumed that L=S (we maintain uniform sampling with equal sampling rates for obtaining the room responses). The choice for the filter order and the modeled impulse response duration affects the gain (13) and distortion (as later defined) of the signal at the microphones. Basically, a lower duration response used for designing the eigenfilter will reduce the operations for computing the eigenfilter, but may affect performance. In summary, the length of the room response (reverberation) modeled in the design of the eigenfilter affects the performance and this variation in performance is referred to as the sensitivity of the eigenfilter to the length of the room response.

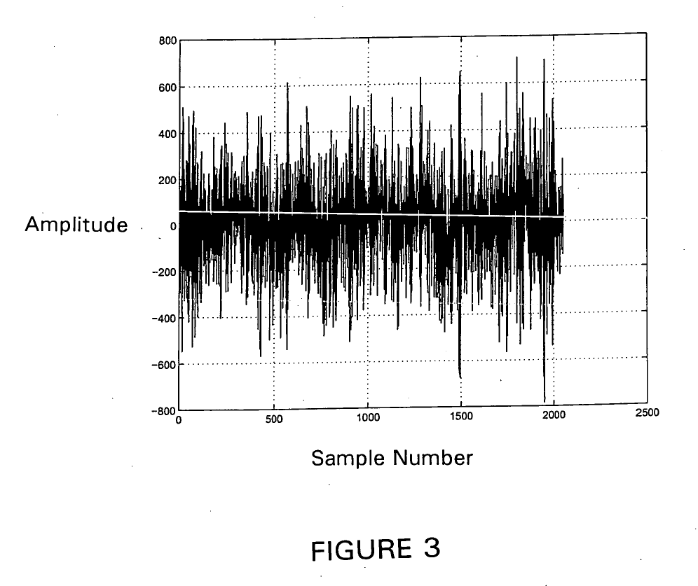

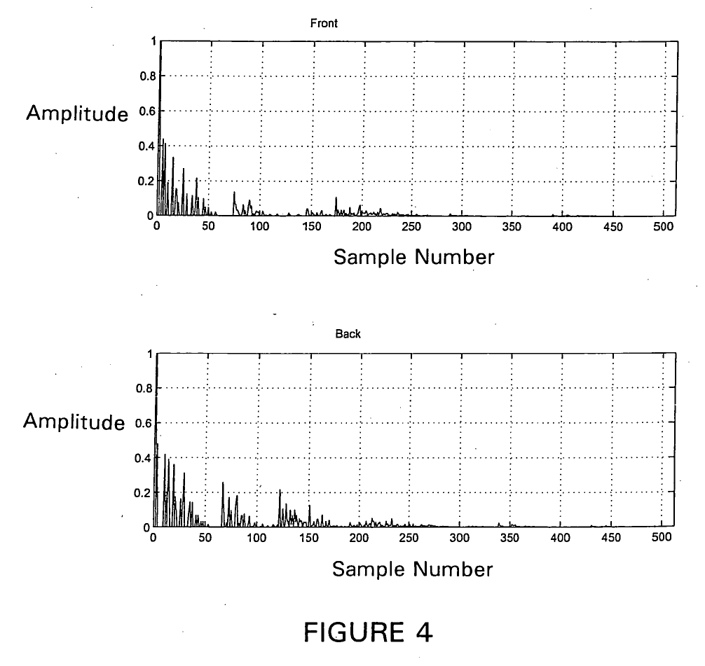

To test the eigenfilter, a segment of speech signal for the unvoiced fricated sound /S/ as in “sat” obtained from a male object as shown in FIG. 3 for x(n). As is well known, this sound is obtained by exciting a locally time-invariant, causal, stable vocal tract filter by a stationary uncorrelated white noise sequence-which is independent from the vocal tract filter. The stability of the vocal tract filter is essential, as it guarantees the stationarity of the sequence x(n). The impulse responses were generated synthetically from the room acoustics simulator software. The estimation of these responses are based on the image method (geometric modeling) of reflections created by ideal omnidirectional sources, and received by ideal omnidirectional receivers. For the present scenario the modeled room was of dimensions, 15 m×10 m×4 m. The source speaker was at (1 m, 1 m, 1 m) from a reference north-west corner. The impulse response for the “front” microphone located at (4.9 m, 1.7 m, 1 m) relative to the reference, was denoted as h₂(n), while the “back microphone” located at (4.5 m, 6.4 m, 1 m) had impulse response measurement h₁(n). The two responses are plotted at positive pressure amplitudes in FIG. 4 (ignoring the initial delay). It will be those responses which would be used to determine the coefficients of the eigenfilter. This situation is similar to the case for listeners in an automobile, where the front left speaker is active, and the relative gain to be maximized is between the front driver and the back passenger.

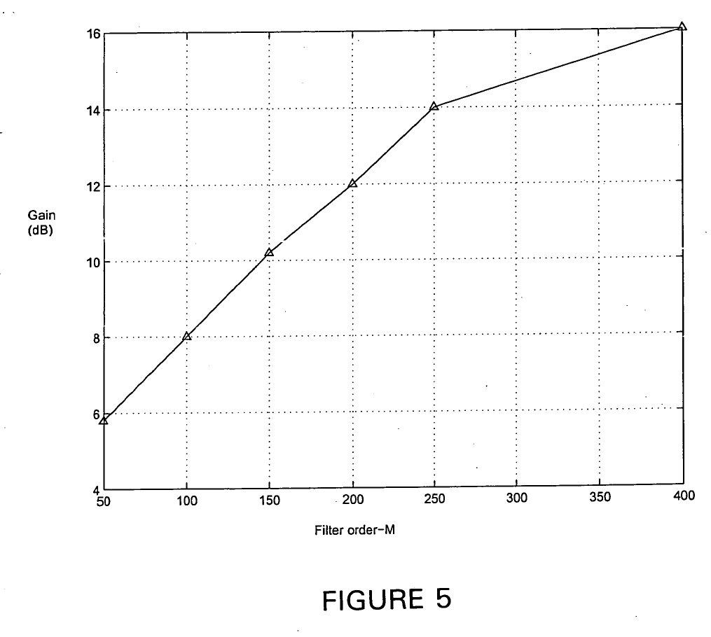

A plot of the gain (13) as a function of the filter order for the aforementioned signal and impulse responses is shown in FIG. 5. Firstly, a different microphone positioning will require a new simulation for computing (12), and determining the performance thereof. Secondly, larger duration filters increase the gain, but affect the signal characteristics at the receiver in the form of distortion. Basically, a distortion measure is an assignment of a non-negative number between two quantities to assess their fidelity. The distortion measure should satisfy the following properties: 1) it must be meaningful, in that, a small and large distortion between the two quantities correspond to good and bad subjective quality, 2) it must be tractable and should be easily tested via mathematical analysis, 3) it must be computable (actual distortions in a real system can be efficiently computed). The proposed distortion measure is evaluated in terms of an Lp,(p=1) norm on (−π,π) and models the variation in the received spectrum at listener 2 due to the presence of the eigenfilter, over the natural event-that of the absence of the filter. The evaluation of the distortion at listener 1 is not important, since the intention is to “cancel” the signal in his direction. The L₁ norm is used due to its ease of analysis and computation for the current problem. Before presenting the results for the distortion against filter order, it was proven as shown below that the average spectrum error (stated in terms of the spectral local matching property [26]) E_{M} is constant for any eigenfilter order.

The spectrum error E_{M} defined in terms of the spectral match is,

$${E}_{M} = {‖ \frac{{S}_{\hat{y}} ( {ⅇ}^{jω} )}{{S}_{y} ( {ⅇ}^{jω} )} ‖}_{1} 1 , ∀ M \qquad ( 29 )$$

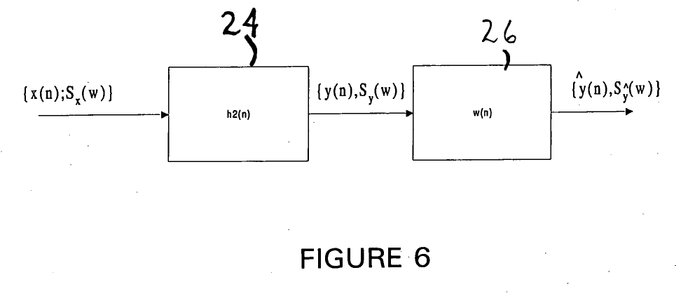

for an M−th order eigenfilter, and

$${S}_{\hat{y}} ( {ⅇ}^{jω} ) = {\vert {H}_{2} ( {ⅇ}^{jω} ) \vert}^{2} {W}_{M} ( {ⅇ}^{jω} ) {\vert}^{2} {S}_{x} ( {ⅇ}^{jω} ) \\ = \vert {W}_{M} ( {ⅇ}^{jω} ) {\vert}^{2} {S}_{y} ( {ⅇ}^{jω} ) \qquad ( 30 )$$

where S_{ŷ(e}^{jω}),Sy(e^{jω}) are the spectra associated with the presence and absence of the eigenfilter respectively (an equivalent model is shown in FIG. 6), and

$${W}_{M} ( {ⅇ}^{jω} ) = \sum \frac{M - 1}{i = 0} {w}_{i} {ⅇ}^{- jω i} .$$

Box 24 represents the acoustic response of the environment and box 26 represents the coefficients of the optimized filter. From the L₁ definition, we have,

$${E}_{M} = {\int }_{- π}^{π} \vert \frac{{S}_{\hat{y}} ( {ⅇ}^{j ω} )}{{S}_{y} ( {ⅇ}^{j ω} )} \vert \frac{ⅆ ω}{2 π} \qquad ( 31 )$$

From (27), (30), and (31) it can be seen that

$${E}_{M} = {\int }_{- π}^{π} \vert {W}_{M} ( {ⅇ}^{j ω} ) {\vert}^{2} \frac{ⅆ ω}{2 π} = 1 \qquad ( 32 )$$

It is interesting to observe that a similar result can be established for the liner prediction spectral matching problem. Also, when the FIR eigenfilter is of the lowest order with M=1, and w₀=1, then the impulse response of the eigenfilter is w(n)=δ(n), and E₁ is unity (observe that with w(n)=δ(n) we have h₂(n)\mathring{x}δ((n)=h₂(n)).

An interpretation of (32) is that irrespective of the filter order (M>1), the average spectral ratio is unity, which means that in terms of the two spectra, S_{\mathring{y}}(e^{jω}) will be greater than S_{y}(e^{jω}) in some regions, and less in other regions, such that (32) holds.

The log-spectral distortion d_{M}(S_{ŷ}(e^{jω}),S_{y}(e^{jω})) for an eigenfilter of order M on an L₁ space is defined as

$$\begin{matrix}{d}_{M} ( {S}_{\hat{y}} ( {ⅇ}^{j ω} ) , {S}_{y} ( {ⅇ}^{j ω} ) ) = {‖ log {S}_{y} ( {ⅇ}^{j ω} ) ‖}_{1} \\ = {‖ log {S}_{\hat{y}} ( {ⅇ}^{j ω} ) / {S}_{y} ( {ⅇ}^{j ω} ) ‖}_{1} \\ = ‖ log {W}_{M} ( {ⅇ}^{j ω} ) {{\vert}^{2} ‖}_{1} \\ = {\int }_{- π}^{π} \vert log \vert {W}_{M} ( {ⅇ}^{j ω} ) {\vert}^{2} \vert \frac{ⅆ ω}{2 π}\end{matrix} \qquad ( 33 )$$

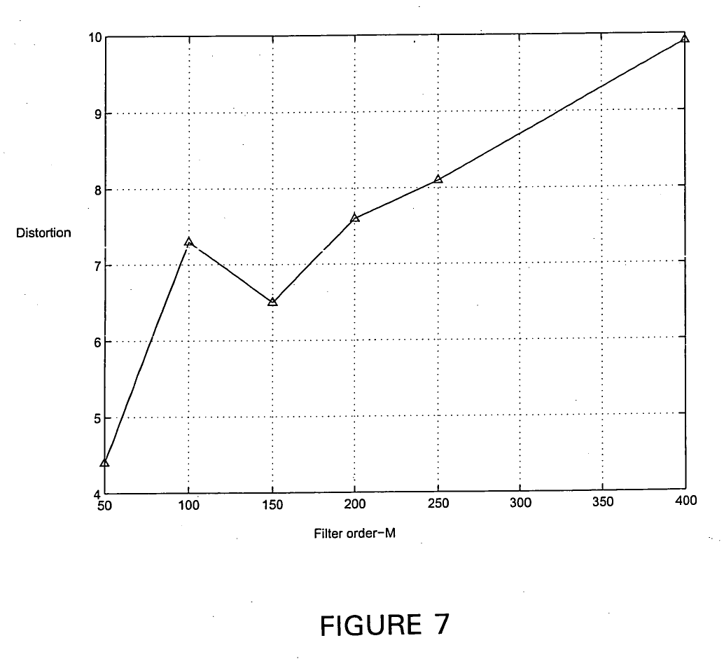

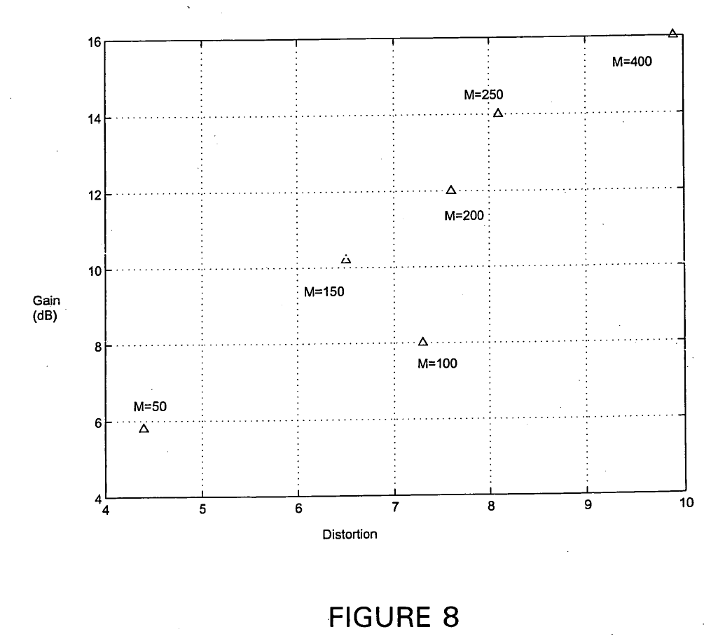

It can be easily shown that d_{M}(S_{ŷ}(e^{jω}),S_{y}(e^{jω}))≧0, with equality achieved when the eigenfilter is of unit order with w₀=1. FIG. 7 illustrates the computation of the distortion (33), using standard numerical integration algorithms, as a function of the filter order for the present problem. FIG. 8 summarizes the results from FIG. 5 and FIG. 7, through the gain-distortion constellation diagram. Thus depending on whether a certain amount of distortion is allowable, a certain point in the constellation is chosen (distortionless performance is obtained for the point located along the positive ordinate axis in the constellation).

Clearly there is an improvement in the gain to distortion ratio with the increase in filter order (for e.g., from FIG. 8, M=400 gives a gain-distortion ratio of 10^{1.6}/9.8≈4, whereas M-250 gives the gain-distortion ratio as 3). Also, for example, with filter order M=400, the relative gain between the two locations is as much as 16 dB. This roughly (and ideally) corresponds to positioning a listener, for whom the sound cancellation is relevant, 2.6 times as far from a fixed source.

From (10), (12), and (13) we see that the eigenfilter performance can be affected by (i) the room response duration modeled in the eigenfilter design, as well as (ii) the nature of the room response (i.e., whether it is characterized by an equivalent minimum phase model or not). In summary, a short duration room response if used in (10), for determining (12), will reduce the computational requirements for designing the eigenfilter. However, this could reduce the performance since the eigenfilter does not use all the information contained in the room responses. This then introduces a performance tradeoff. The question then is, can an eigenfilter (12) be designed with short duration room response (for savings in computation) in the A and B matrices in (10), but yet does not cause the performance (13) to be affected. Of course, care should be taken to evaluate the performance in that, the A and B matrices in (13) should have the full duration room responses.

To understand this performance tradeoff, an eigenfilter of length M<L (L being the actual duration of the room impulse responses in the two directions), based on who designed both room responses with the window being rectangular and having duration P<L. The performance (13) of the filter to increasing room response length was then analyzed. Basically the goal of this endeavor was to design an eigenfilter with sufficiently short room responses (in (12)) without compromising the performance. The following procedure was adopted for this endeavor. An eigenfilter ŵ* ∈ R^{M×1} for a shortened room response duration P<L,

ŵ*=e_{λ max[\hat{B}}_{⁻¹}_{Â]} (34)

with,

$$\hat{A} = {\sum }_{p = 0}^{P - 1} {\sum }_{q = 0}^{P - 1} {h}_{2} ( p ) {h}_{2} ( q ) {R}_{\underline{x}} ( p , q ) \\ \hat{B} = {\sum }_{p = 0}^{P - 1} {\sum }_{q = 0}^{P - 1} {h}_{1} ( p ) {h}_{1} ( q ) {R}_{\underline{x}} ( p , q ) \\ M \leq P < L \qquad ( 35 )$$

was used wherein, the hat above the matrices in (35) denotes an approximate to the true quantities in (10), and the corresponding eigenfilter (34) is the resulting approximation (due to reduced duration P>L to (12). The constraint M≦P>L was included to keep the order of the eigenfilter low (reduced processing), for a given real room response duration L=8192, as explained below.

The performance (13) of the filter with the true matrices A and B (10) containing the full duration room responses was then evaluated.

The performance responses were selected according to a) hᵢ(n)=h_{i,min}(n) [symbol] h_{i,ap}(n), and b) hᵢ(n)=H_{i,min}(n);i=1,2; where h_{i,min}(n) and h_{i,ap}(n) (comprising of 8192 points) were obtained in a highly reverberant room from the same microphones.

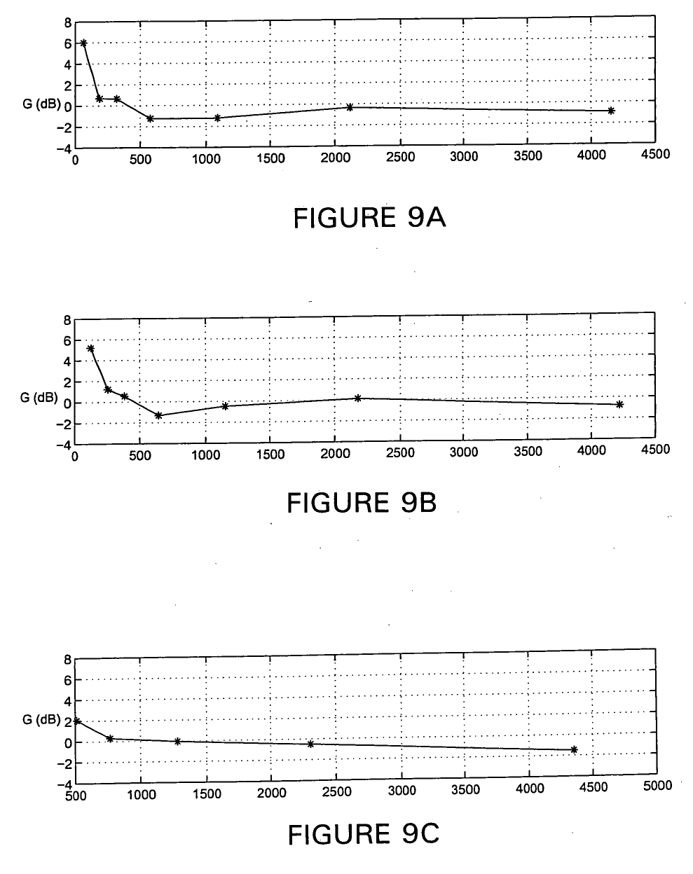

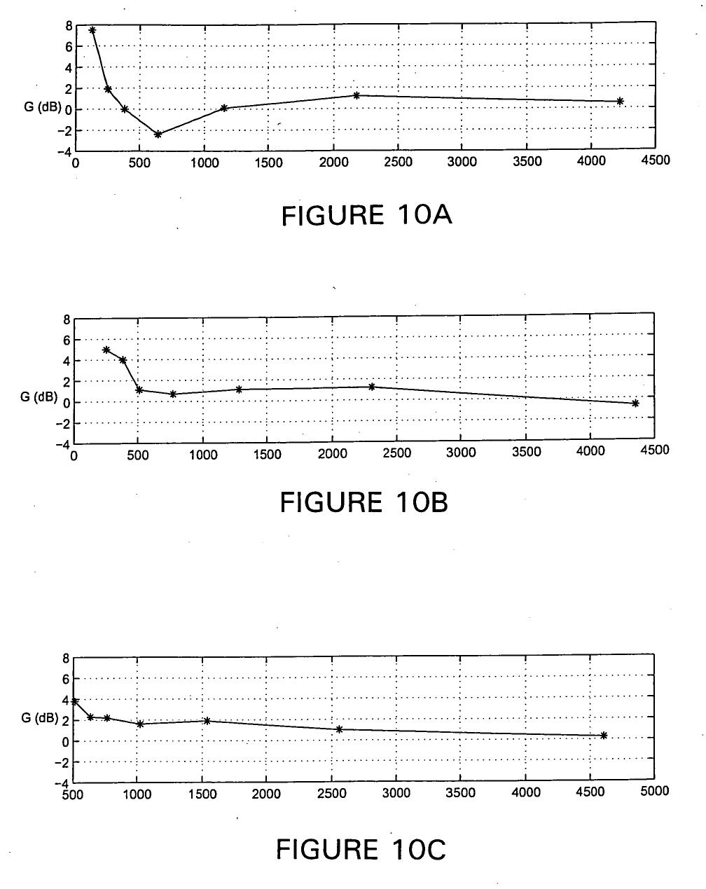

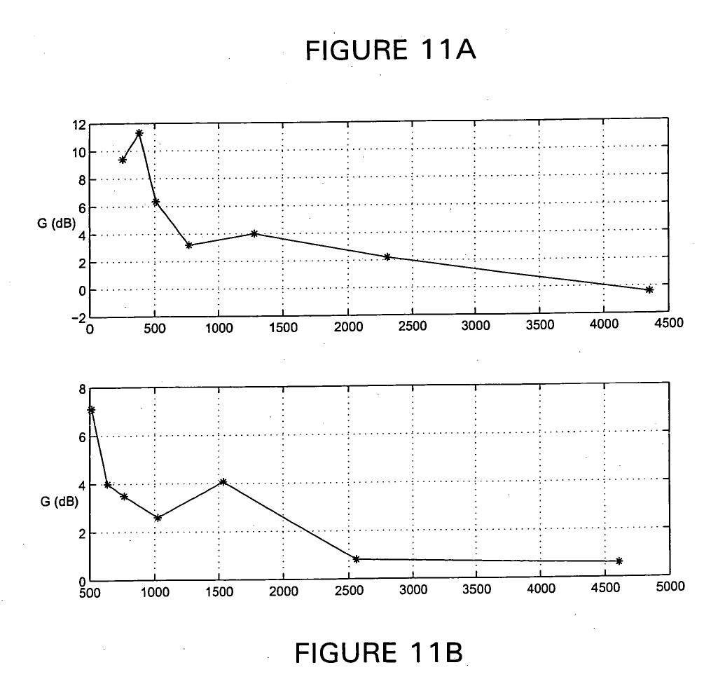

Using hᵢ(n)=h_{i,min}(n) [symbol] h_{i,ap}(n);i1,2, FIG. 9 shows the performance of the eigenfilter design as a function of the length of the impulse response. The length of the FIR filter was M=64. The performance in each subplot as a function of the impulse response increments is shown, where ΔP={0}∪ {2^{k}:k ∈ [7,12],k ∈ I}, where I denotes the integer set was chosen. Thus, FIG. 9(A), represents an eigenfilter of length M=64 designed with duration P, of the windowed impulse response, to be 64 (after removing the pure delay). FIG. 9(B) uses P=128 and FIG. 9(C) uses P=512. The second performance evaluation, marked by an asterisk (*), is at P+ΔP=64+2⁷=192. In FIG. 10 and FIG. 11, the sensitivity of the eigenfilter for filter length M=128, and M=256 for various windowed room impulse responses is shown. FIG. 10(A) uses P=128. FIG. 10(B) uses P=256 and FIG. 10(C) uses P=512. FIG. 11(A) uses a filter length of 256 and P=256. FIG. 11(B) uses a filter length of 256 and P=512.

From the figures, it can be seen that a better gain performance with increased filter length is confirmed. By considering a larger duration room impulse response in the eigenfilter design, the gain is lowered relatively but its evenness is improved (flatness). Ideally, a small duration filter length (relative to the length of the room responses) with a large gain and uniform performance (low sensitivity to the length of the room impulse response) is desired.

Using hᵢ(n)=h_{i,min}(n);i=1,2 and as shown in FIGS. (12)-(14), the performance of the eigenfilter for various windowed room responses and with different filter lengths is illustrated. The performance (in terms of uniformity and level of the gain) is better than the nonminimum phase impulse response model.

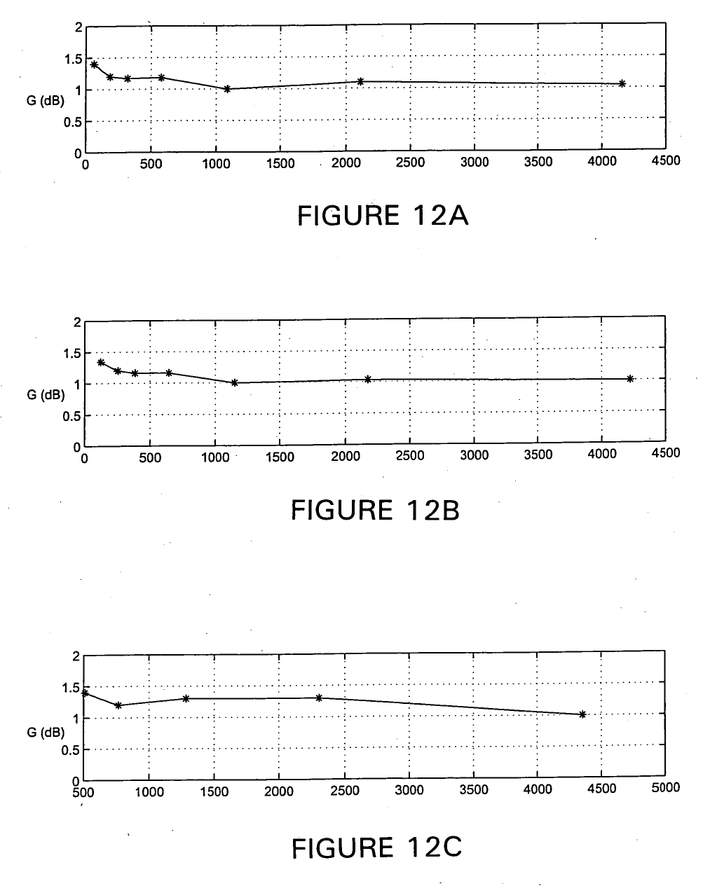

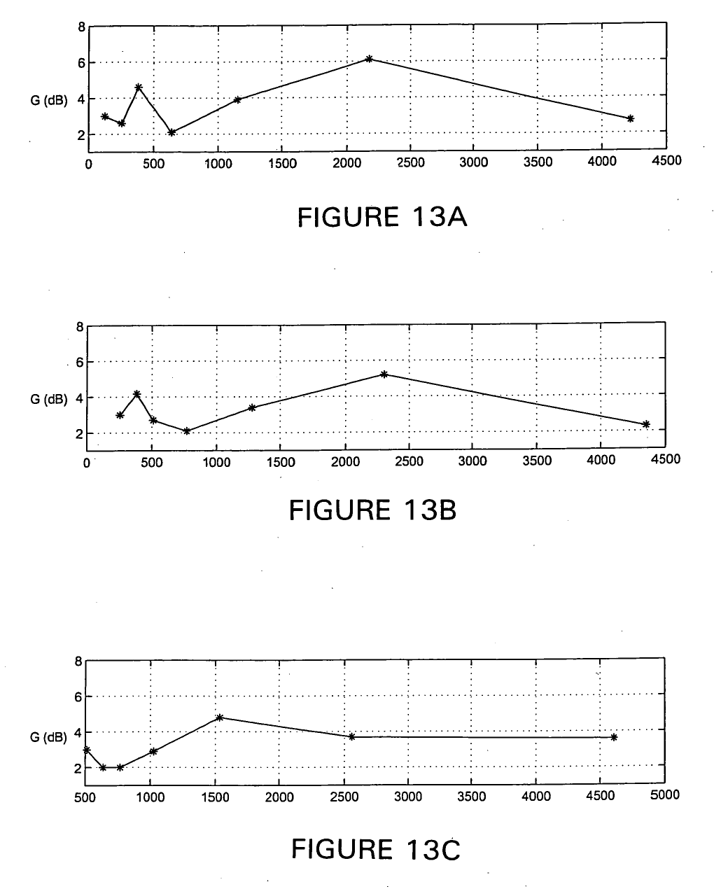

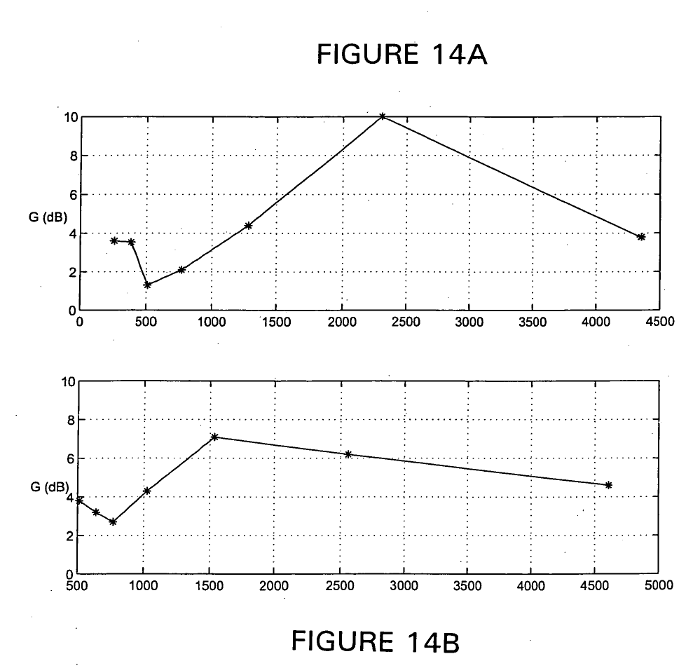

FIG. 12 uses a matrix length of M=64. FIG. 12(A) uses P=64, FIG. 12(B) uses P=128 and FIG. 12(C) uses P=512. FIG. 13 uses a matrix length of M=128, FIG. 13(A) uses P=128, FIG. 13(B) uses P=256 and FIG. 13(C) uses P=512. FIG. 14 uses a filter length of M=256 with P=256 in FIG. 14(A) and P=512 in FIG. 14(B).

As can be appreciated by the above calculations, the utilization of the eigenfilter to produce an audio signal to be heard by one listener in a particular environment but would be minimized or completely unheard by the second listener in the environment, it is crucial to determine the exact positions of these listeners in the environment. For purposes of the present explanation, we will assume that only two listeners are present in the environment. As previously explained, the present invention would produce a signal by processing a raw audio signal through a filter which maximizes an objective function as shown in equation (3). This equation includes a first term to maximize the signal power or gain heard by a second listener and a second term which would minimize the gain and signal power and therefore the audio signal heard by the first listener.

The position of each listener with respect to the loudspeaker for producing the audio signal, and for that matter the positioning between each of the listeners is determined by the utilization of a test program. A transceiver is first placed in the position of the first listener (16) (FIG. 2) and a test signal is generated to be received by the transceiver. The transceiver would then produce a signal which is reflected back to the loudspeaker (22) which also acts as a receiver. Once this first portion of the test sequence has been completed, the transceiver is then moved to the position of the second listener at which time the test signal is retransmitted to be received by the transceiver in the second position. At this point, the transceiver placed at the position of the second listenerwould then produce a signal which is reflected back to the loudspeaker. Software associated with the test sequence and a processing device would utilize this information to maximize the objective function shown in equation (3) by determining the optimal filter coefficients in equation (12) as well as the gain between the two receiver locations expressed in equation (13). Therefore, during operation of the audio device in the listening environment, the raw signal would be processed through the eigenfilter with the proper coefficients as determined by equation (12) to produce a gain as determined by equation (13). This gain would be maximized at listener 2 but would be minimized or completely eliminated as received by listener 1. It is noted that the processing circuitry utilized to determine the proper coefficients of the eigenfilter as well as the gain could be accomplished locally with respect to the listening environment or at a location remote from the listening environment.

When used in a listening environment such as an automobile, a home theater or the like, provisions can be made in the form of a switch or switches which would indicate which of the listening positions would hear the maximum signal and which of the positions would hear a minimum or a completely cancelled signal. It could also be appreciated that if both of the listeners would desire to hear the maximized signal, the raw audio signal would bypass the eigenfilter.

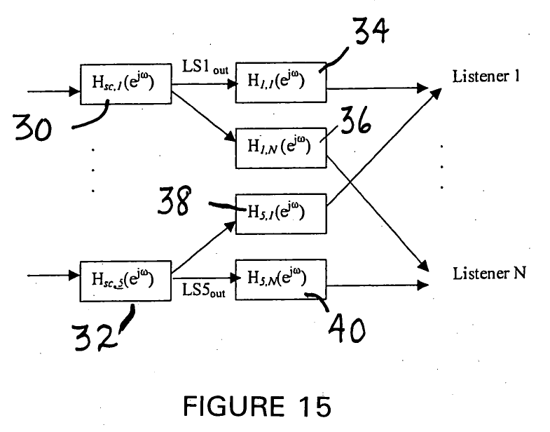

The objective function shown in equation (3) contains two terms, the first of which would maximize the sound pressure level or gain heard by one of the listeners and the second term constraining the sound pressure level to the other listener. As can be appreciated, the teachings of the present invention can be extended to a listening environment having a number of listening positions, as well as a plurality of loudspeakers shown in FIG. 15. In this instance, the test program would be run with the transceiver at each of the listening positions in turn. Once the test procedure was completed, and a first set of positions is designated to hear the maximum audio output and a second set of positions is denoted to not hear or minimize the audio output, each of the set of room acoustical responses generated by each of the sets would be averaged. Once this accomplished, the proper coefficients of one of several eigenfilters would be determined to produce a set of signals which is substantially cancelled at a first set of positions and effectively optimized at the second set of positions. Each of the signals would be generated by one of a plurality of loudspeakers. As was true with the discussion of the embodiment including only two listening positions, a switch or series of switches or like devices would be used to indicate which particular listening position belong to the first set of positions or the second set of positions.

Referring again to FIG. 15, blocks (30) and (32) represent separate eigenfilters, each of which is associated with separate loudspeakers. Although the exact number of loudspeakers is unimportant for the teaching of the present invention, FIG. 15 does show a system providing five loudspeakers. Boxes (34), (36), (38) and (40) represent the signal which would be heard by any one of N listeners. Therefore, as shown in FIG. 15, eigenfilter (30) would produce an output from loudspeaker (1) which would be perceived by the listeners N differently due to the fact that they are in different positions of the listening environment.

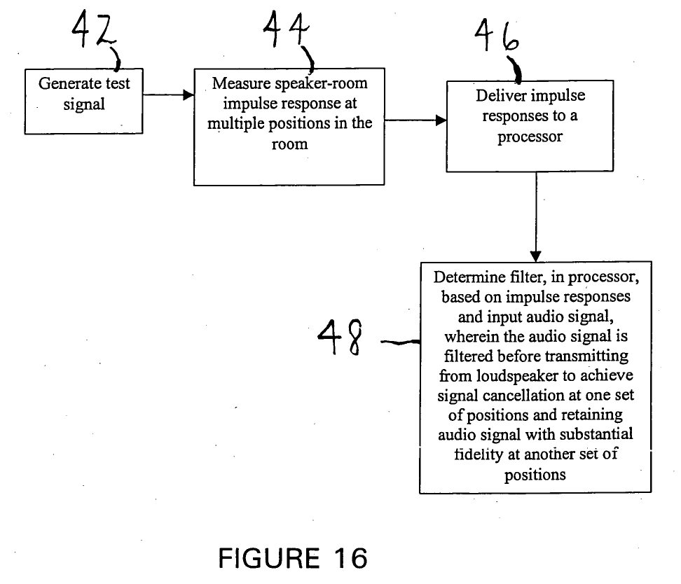

FIG. 16 illustrates the generalized method and system of the present invention. Initially, a test signal is generated at (42) from one or more of the loudspeakers discussed with respect to FIGS. 2 and 15. A transceiver is placed in one or more positions in the listening environment and the impulse response at these various positions in the listening environment are measured at (44). Based upon these measured responses impulse responses are provided to a processor at (46). This processor at (48) maximizes an objective function by provided the proper outputs to an eigenfilter associated with each of the loudspeakers. As previously indicated, FIG. 2 illustrates a system in which a single loudspeaker is provided thereby requiring only a single eigenfilter. FIG. 15 shows a system utilizing multiple loudspeakers, and therefore, a separate eigenfilter is provided for each of the loudspeakers. A raw audio signal is then passed through the eigenfilter or eigenfilters to achieve signal cancellation at one set of positions within the listening environment while retaining the audio signal with substantial fidelity at another set of positions. This process audio signal is then transmitted into the listening environment as shown.

While the present invention has been described in detail with reference to a particular embodiment, and to other options presently known to the inventors, the invention should not be considered as limited thereto or thereby. Various modifications within the spirit and scope of the invention will be apparent to ordinarily skilled artisans.

What is claimed is:

1. A method for selectively presenting an audio signal to an environment having at least two listening positions, comprising the steps of:
measuring an acoustical response at a first listening position;
creating a filter by determining the gradient of an objective function, said objective function including a first term;
producing a raw audio signal;
processing said raw audio signal through said filter to produce a filtered audio signal, wherein said first term minimizing the second pressure level of said filtered audio signal at said first listening position;
transmitting said filtered audio signal from at least one loudspeaker provided within the environment, said filtered audio signal substantially cancelled at said first listening position and substantially retained at a second listening position.

2. The method of claim 1, further comprising the step of measuring an acoustical response at said second listening position.

3. The method of claim 2, further comprising the step of including a first term in said objective function for maximizing the sound pressure level of said filtered audio signal at said second listening position.

4. The method of claim 1, further comprising the step of including a second term in said objective function for constraining the sound pressure level of said filtered audio signal at said first listening position by a predetermined amount.

5. The method of claim 2, further comprising the step of including a second term in said objective function for constraining the sound pressure level of said filtered audio signal at said second listening position by a predetermined amount.

6. The method of claim 1, further including the step of transmitting a test signal from said at least one loudspeaker to measure an acoustical response in the environment.

7. The method of claim 6, further including the step of transmitting a plurality of test signals from said at least one loudspeaker to measure an acoustical response from each of the listening positions in the environment.

8 The method of claim 7, further including the step of providing a transceiver at each of the listening positions to produce a signal from each of the listening positions to measure an acoustical response from each of the listening positions in the environment.

9. The method of claim 3, further including the steps of:
transmitting a test signal from said at least one loudspeaker to measure an acoustical response in the environment, and
producing a first term of said objective function which is a function of said acoustical response.

10. The method of claim 4, further including the steps of:
transmitting a test signal from said at least one loudspeaker to measure an acoustical response in the environment, and
producing a second term of said objective function which is a function of said acoustical region.

11. The method of claim 1, wherein at least two listening positions includes a first set of listening position at which said filtered audio signal is substantially cancelled and a second set of listening positions at which said filtered audio signal is substantially retained, comprising the step of:
transmitting a test signal from said at least one loudspeaker to measure a first set of acoustical responses at said first set of listening positions.

12. The method of claim 11, wherein at least two listening positions includes a second set of listening positions at which said filtered audio signal is substantially cancelled and a second set of listening positions at which said filtered audio signal is substantially retained, comprising the step of:
transmitting a test signal from at least one loudspeaker to measure a second set of acoustical responses at said second set of listening positions.

13. The method of claim 11, further including the step of:
producing a first term of said objective function which is a function of said acoustical response.

14. The method of claim 12, further including the step of:
producing a second term of said objective function which is a function of said acoustical region.

15. The method claim 11, further including the step of averaging said first set of acoustical responses.

16. The method of claim 12, further including the step of averaging said second set of acoustical responses.

17. A system for selectively presenting an audio signal to an environment having at least two listening positions, comprising:
test signal production device for producing a test signal to be projected into the environment;
transceiver device provided within the environment for receiving said test signal and providing an acoustical response returned to said test signal production device;
a means for creating a filter by determining the gradient of an objective function based upon said response returned to said test signal production device, wherein said objective function includes a first term for minimizing the second pressure at a first listening position;
transmitting a raw audio signal through said filter to produce a filtered audio signal; and
projecting said filtered audio signal into the environment.

18. The system in accordance with claim 17 including a selection device for choosing whether a particular listening position wishes to receive a maximized filtered audio signal or a minimized signal filtered audio signal.

19. The system in accordance with claim 18 in which the environment includes a second listening position to receive said maximized filtered audio signal, wherein said means for creating a filter produces a first term of said objective function for minimizing the sound to pressure level of said filtered audio signal and a second term of said objective function for maximizing the sound pressure level of said filtered audio output.

20. The system in accordance with claim 18 in which the environment includes a first set of listening positions to receive said maximized filtered audio signal and a second set of listening positions to receive said minimized filtered audio signal, wherein said means for creating a filter produces a first term of said objective function for minimizing the sound pressure level of said filtered audio signal and a second term of said objective function for maximizing the sound pressure level of said filtered audio output.

21. The system in accordance with claim 20, wherein said means for creating said filter averages the acoustical responses received from said first set of listening positions to produce said first term and said filter averages the acoustical responses received from said second set of listening positions to produce said second term.
